(19) United States
(12) Patent Application Publication
(10) Pub. No.: US 2026/0180515 A1
(43) Pub. Date: Jun. 25, 2026

(54) PACKAGED AMPLIFIER DEVICES WITH SPLITTER AND IMPEDANCE MATCHING CIRCUITS AND MULTIPLE-STAGE, MULTIPLE-PATH POWER AMPLIFIERS

(71) Applicant: NXP USA, Inc., AUSTIN, TX (US)

(72) Inventors: Ricardo Douglas Toledo, Gilbert, AZ (US); Vikas Shilimkar, Chandler, AZ (US); Joseph Gerard Schultz, Wheaton, IL (US)

(21) Appl. No.: 18/988,983

(22) Filed: Dec. 20, 2024

(51) Int. Cl. H03F 1/02; H01L 23/66; H01L 25/18; H03F 3/24

(52) U.S. Cl. CPC H03F 1/0288; H03F 3/245; H10W 44/20; H10W 90/00; H03F 2200/451; H10W 44/234

(57) ABSTRACT

A packaged amplifier device includes a device input terminal, first and second device output terminals, a power amplifier, a power splitter circuit, and first and second impedance matching circuits coupled to a package body. The power amplifier includes a transistor, a transistor input terminal electrically coupled to the device input terminal, and a transistor output terminal. The power splitter circuit includes a splitter input terminal electrically coupled to the transistor output terminal, a first splitter output terminal, and a second splitter output terminal. The first impedance matching circuit is directly connected to the first splitter output terminal and to the first device output terminal, and the second impedance matching circuit is directly connected to the second splitter output terminal and to the second device output terminal. A multiple-stage, multiple-path power amplifier includes the packaged amplifier device and additional amplifier transistors coupled to the first and second device output terminals.

### TECHNICAL FIELD

Embodiments of the subject matter described herein relate generally to power amplifiers, and more particularly to multiple-stage, multiple-path power amplifiers with driver and final amplification stages, power splitters, and interstage impedance matching circuits.

### BACKGROUND

Wireless communication systems employ power amplifiers for increasing the power of radio frequency (RF) signals. In a cellular base station, for example, a Doherty power amplifier may form a portion of the last amplification stage in a transmission chain before provision of the amplified signal to an antenna for radiation over the air interface. High gain, high linearity, stability, and a high level of power-added efficiency are characteristics of a desirable power amplifier in such a wireless communication system. With an ever-increasing trend towards integration and miniaturization, power amplifier designers are challenged to design amplifiers that are easy to integrate and that have relatively small size (e.g., utilize a relatively small amount of PCB space).

### BRIEF DESCRIPTION OF THE DRAWINGS

A more complete understanding of the subject matter may be derived by referring to the detailed description and claims when considered in conjunction with the following figures, which are not necessarily drawn to scale, and wherein like reference numbers refer to similar elements throughout the figures.

FIG. 1 is a schematic circuit diagram of a multiple-stage, multiple-path power amplifier, in accordance with one or more example embodiments;

FIG. 2 is a top view of a multiple-stage, multiple-path power amplifier implemented on a system substrate, in accordance with one or more embodiments;

FIG. 3 is a top view of a packaged amplifier device, in accordance with one or more example embodiments;

FIG. 4 includes top and side, cross-sectional views of a passive device assembly that houses a power splitter circuit, in accordance with one or more example embodiments;

FIG. 5 includes top and side, cross-sectional views of a passive device assembly that houses a portion of an impedance matching circuit, in accordance with one or more example embodiments; and

FIG. 6 is a cross-sectional, side view of the power amplifier of FIG. 2 along line 6-6, in accordance with one or more example embodiments.

### DETAILED DESCRIPTION

Embodiments of packaged amplifier devices (e.g., surface mount devices) are disclosed herein that include a power amplifier, a power splitter circuit, and first and second impedance matching circuits coupled to a package body. The packaged amplifier devices may be used, for example, as a first amplification stage (e.g., a driver amplification stage) in a multiple-stage, multiple-path power amplifier, such as a Doherty power amplifier. To implement the multiple-stage, multiple-path power amplifier, the packaged power amplifier device may be coupled to a system substrate along with a second amplification stage (e.g., a final amplification stage) in each of the multiple amplifier paths.

Because the power amplifier, the power splitter circuit, and the first and second impedance matching circuits are included within the packaged power amplifier device, the overall size of the multiple-stage, multiple-path power amplifier may be reduced, in comparison with conventional multiple-stage, multiple-path power amplifiers. In addition, the first and second impedance matching circuits provide first stages of first and second interstage matching circuits between the power splitter outputs and inputs to the second amplification stages. By integrating the first and second impedance matching circuits within the packaged power amplifier device, other portions of the interstage matching circuits that are implemented between the packaged power amplifier device and the inputs to the second amplification stages may be greatly simplified, in comparison with conventional multiple-stage, multiple-path power amplifiers.

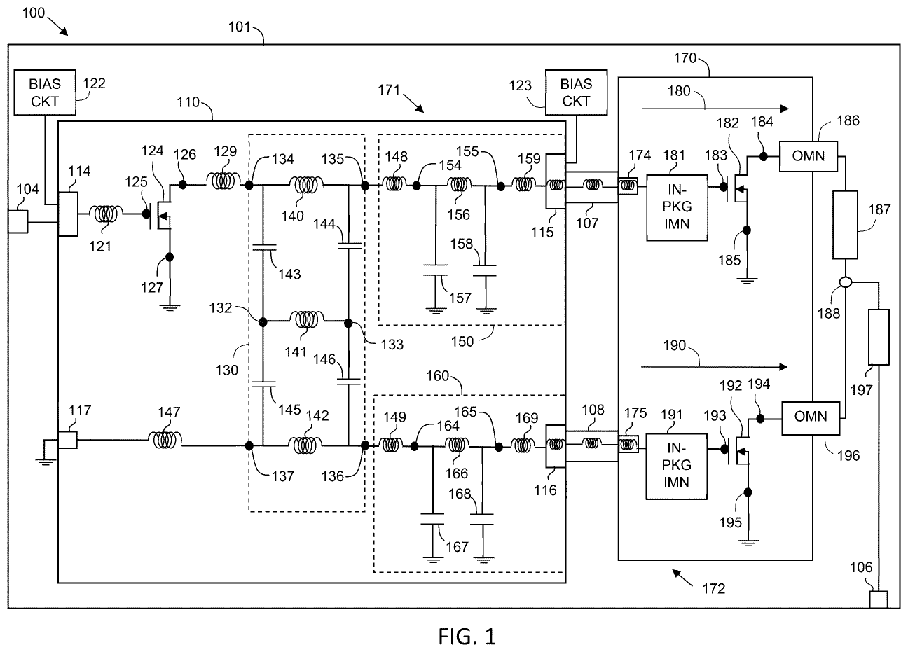

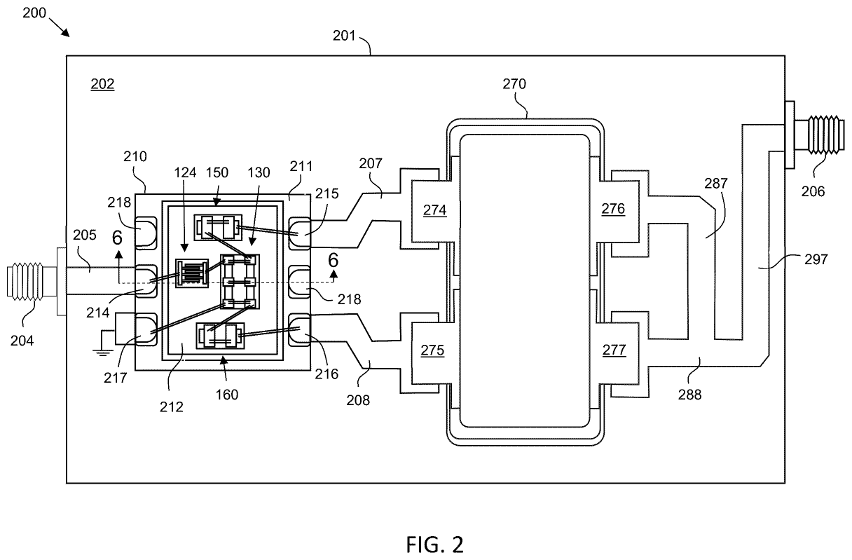

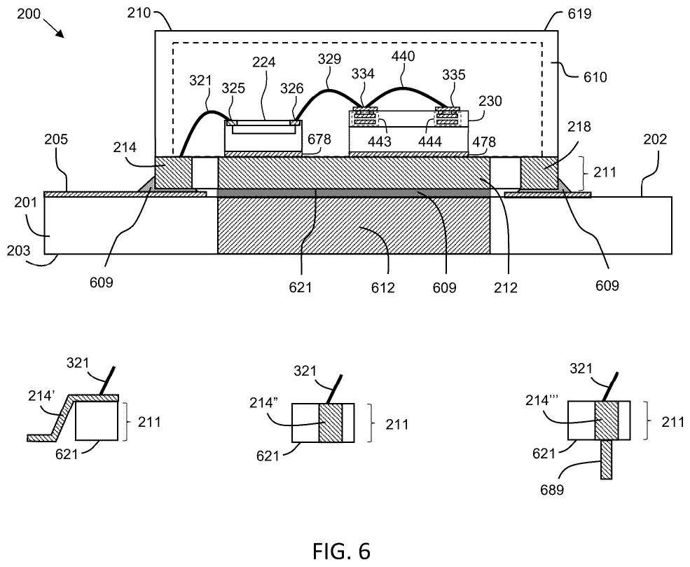

FIG. 1 is a schematic circuit diagram of a multiple-stage, multiple-path power amplifier 100, in accordance with one or more embodiments. For enhanced understanding, FIG. 1 should be viewed simultaneously with FIGS. 2 and 6, where FIG. 2 is a top view of a physical implementation of a multiple-stage, multiple-path power amplifier 200 (e.g., amplifier 100 of FIG. 1), and FIG. 6 is a cross-sectional, side view of the power amplifier 200 of FIG. 2 along line 6-6, in accordance with one or more embodiments. More specifically, the multiple-stage, multiple-path power amplifiers 100, 200 depicted in FIGS. 1, 2, and 6 are Doherty power amplifiers. However, those of skill in the art would understand, based on the description herein, that embodiments of the inventive subject matter could be used in other types of multiple-stage, multiple-path power amplifiers, as well. Therefore, discussion of the various embodiments in the context of Doherty power amplifiers is not meant to limit the scope of the inventive subject matter only to Doherty power amplifiers.

As a brief overview, the multiple-stage, multiple-path power amplifier 100, 200 includes an input terminal (e.g., terminal 104, 204) configured to receive an input signal (e.g., a radio frequency (RF) signal), a first amplification stage (provided by power transistor 124) configured to amplify the input signal, a power splitter (provided by power splitter circuit 130) configured to divide a power of the amplified input signal into first and second amplified signals, a first amplifier path (e.g., amplifier path 180) configured to further amplify the first amplified signal, a second amplifier path (e.g., amplifier path 190) configured to further amplify the second amplified signal, a combining node (e.g., node 188, 288) configured to combine the further amplified first and second signals, and an output impedance transformer circuit (e.g., circuit 197, 297) coupled between the combining node and an output terminal (e.g., terminal 106, 206).

As will be described in detail below, an interstage matching network 171, 172 is implemented along each of the amplifier paths 180, 190 between the power splitter circuit 130 and the input terminals (e.g., gate terminals 183, 193) of the power transistors (e.g., transistors 182, 192. Each interstage matching network 171, 172 includes several stages that are connected in series. This includes a first stage provided by first and second impedance matching circuits 150, 160 within a driver amplifier and splitter device 110, 210, a second stage provided on a system substrate 101, 201 (e.g., by traces 107, 108), and a third stage provided by first and second impedance matching networks 181, 191 within a final stage amplifier device 170, 270.

Including the first and third impedance matching stages in the devices 110, 210, 170, 270, as explained below, enables the second-stage matching on the system substrate 101, 201 to be simplified, in comparison with how interstage matching is achieved in conventional amplifiers. Specifically, a device supplier may design both the driver amplifier and splitter device 110, 210 and the final stage amplifier device 170, 270 to include first and third impedance matching stages that accomplish most of the desired interstage impedance transformation, and the overall amplifier designer may therefore need to design only a simple additional impedance match on the system substrate 101, 201. Enabling a simplification of the additional impedance match on the system substrate 101, 201 may, in turn, result in reduced amplifier development time and cost, and further may enable more compact amplifier designs.

According to one or more embodiments, amplifier 100, 200 includes a system substrate 101, 201. In addition, amplifier 100, 200 includes a system input terminal 104, 204, a system output terminal 106, 206, a driver amplifier and splitter device 110, 210 (“first packaged amplifier device”), and a final stage amplifier device 170, 270 (“second packaged amplifier device”) coupled to the system substrate 101, 201.

The system substrate 101, 201 may be, for example, a printed circuit board (PCB) or another suitable substrate. Referring to FIGS. 2 and 6, the system substrate 201 has a mounting surface 202 and an opposite bottom surface 203. In one or more embodiments, as shown in FIG. 6, the system substrate 201 also may include one or more thermal dissipation structures (e.g., conductive coins and/or conductive thermal vias), such as structure 612, that extend between the mounting and bottom surfaces 202, 203 of the system substrate 101, 201. The first and second packaged amplifier devices 110, 170, 210, 270 may be coupled to the mounting surface 202 of the system substrate 101, 201 over the thermal dissipation structures (e.g., using solder 609 or conductive epoxy), and the thermal dissipation structures may function to convey heat produced by the driver amplifier and splitter device 110, 210 and/or the final stage amplifier device 170, 270 away from those devices (e.g., toward or to a heat sink) during operation of the system 100, 200.

Referring to FIGS. 2 and 6, the driver amplifier and splitter device 110, 210 is a surface mount device (SMD). Various embodiments of the package type for the driver amplifier and splitter device 110, 210 will be described briefly before turning to a detailed description of the amplifier circuitry. According to one or more embodiments, device 110, 210 has a rectangular (e.g., square) perimeter defined by first, second, third, and fourth sides (not numbered) that extend between a top surface 619 and an opposed bottom (or substrate-facing) surface 621.

Device 110, 210 includes a leadframe with a central thermal pad or flange 212 and a plurality of terminals (e.g., terminals 214, 215, 216, 217, 218), which are electrically isolated from each other and held in fixed orientation with respect to each other by a lower package body 211. Referring to FIGS. 1 and 2, terminal 214 corresponds to terminal 114, terminal 215 corresponds to terminal 115, terminal 216 corresponds to terminal 116, and terminal 217 corresponds to terminal 217. Terminals 218 are “extra” terminals that may be coupled to a ground reference node or left electrically floating.

The lower package body 211 has opposed top and bottom surfaces, where the top surface of the lower package body 211 is internal to the device 110, 210, and the bottom surface of the lower package body 211 corresponds to the bottom surface 621 of the device 110, 210. According to an embodiment, the lower package body 211 may be formed from a molded plastic encapsulant material, although in other embodiments, the lower package body 211 may be formed from ceramic or another high-dielectric material. It should be noted that, as used herein, the term “package body” includes, at least, the lower package body 211 and the flange 212.

The flange 212 is an electrically- and thermally-conductive, solid structure, which is centrally-located in the lower package body 211, and which extends between the top and bottom surfaces of the lower package body 211. More particularly, a top surface of the flange 212 is co-planar with the top surface of the lower package body 211, and a bottom surface of the flange 212 is co-planar with the bottom surface of the lower package body 211 (and with the bottom surface 621 of the device 110, 210). The flange 212 may be formed, for example, from bulk conductive material (e.g., copper), which may or may not be plated. Alternatively, the flange 212 may be formed from a composite (e.g., layered or multi-part) conductive structure. According to one or more embodiments, the bottom surface of the flange 212 is physically and electrically connected (e.g., with solder connection 609, conductive adhesive, or other materials) to the mounting surface 202 of the system substrate 201.

According to an embodiment, sets of terminals (e.g., subsets of terminals 214-218) are located at or proximate to two opposing sides of the lower package body 211. Accordingly, the driver amplifier and splitter device 110, 210 may include a Dual Flat No-Lead (DFN) package. Specifically, in FIG. 2, three aligned terminals are located at each of two opposing sides of the lower package body 211. Alternatively, more or fewer terminals may be located at or proximate to each of the sides. According to one or more other alternate embodiments, rather than utilizing a DEN package, the device 110, 210 may include a Quad Flat No-Lead (QFN) package, which includes terminals on all four sides of the package.

Sometimes alternatively referred to as “leads,” “lands,” or “pins,” each of the terminals 214-218 also are formed from bulk electrically conductive material (e.g., copper), which may or may not be plated. Alternatively, the terminals 214-218 may be formed from a composite (e.g., layered or multi-part) conductive structure. In some embodiments, each terminal 214-218 is a roughly cubic structure with a top surface (or an “internal end” or “proximal end”) that is exposed at and/or co-planar with the top surface of the lower package body 211, a bottom surface (or an “external end” or “distal end”) that is co-planar with the bottom surface of the lower package body 211 (and the bottom surface 621 of the device 110, 210), and four side surfaces extending between the top and bottom surfaces.

The internal end (e.g., the top surface) of each terminal 214-218 is at a height above the bottom surface 621 of the device (and thus is at a height above the mounting surface 202 of the system substrate 101, 201). According to an embodiment, this height, which essentially corresponds to the thickness of the terminals (i.e., the distance between the top and bottom surfaces of each terminal), is in a range of about 0.2 millimeters (mm) to about 0.5 mm, in an embodiment. The bottom surface of each terminal 214-218 is exposed at the bottom surface of the lower package body 211 (and at the bottom surface 621 of the device 110, 210), and one of the side surfaces of each terminal 214-218 may be exposed at a side of the lower package body 211. In other embodiments, a side surface of a terminal 214-218 may not be exposed at a side of the lower package body 211 (e.g., a portion of the lower package body 211 may be present between the terminal and the sides of the device 110, 210). Either way, the terminal configuration ultimately facilitates robust connections (e.g., solder connections 609 or connections to a socket) of the terminals to conductive structures (e.g., transmission lines 205, 207, 208) at the mounting surface 202 of the system substrate 101, 201.

Although terminals 214-218 are described to be roughly cubic structures that form portions of a leadframe, each terminal 214-218 alternatively may have more or fewer than four sides, or may have shapes that are other than cubic. For example, in an alternate embodiment, rather than utilizing a DEN or QFN package, the device 110, 210 may include a Quad Flat Package (QFP). Essentially, a QFP differs from a DFN or QFN package in that the QFP includes gull wing terminals (e.g., the gull wing terminal 214′shown in the bottom left corner of FIG. 6, rather than bulk conductive terminals 214-218).

In still another alternate embodiment, the device 110, 210 may include a Land Grid Array (LGA) or a Ball Grid Array (BGA) that includes an array of lands, balls, or pins at the bottom surface 621 of the lower package body 211. Two embodiments of LGA terminals 214″, 214′″ are shown at the lower center and lower right corner of FIG. 6, respectively. LGA terminal 214″ is inset from the side of the lower package body 211, and extends between a top or proximal end at the top surface of the lower package body 211, and a bottom or distal end at the bottom surface of the lower package body 211. The bottom end functions as a land, which may be solder attached to a corresponding contact on the top surface of the system substrate 201, or that may be contacted by a conductive pin protruding from the system substrate 201. In some embodiments, such a conductive pin may protrude into the terminal 214″ (i.e., each terminal 214″ actually functions as a single-pin socket).

LGA terminal 214′″ also is inset from the side of the lower package body 211, and has a portion that extends between a top or proximal end at the top surface of the lower package body 211 and the bottom surface of the lower package body 211. However, LGA terminal 214′″ also includes a pin 689 that protrudes from the bottom surface of the lower package body 211, and an end of the pin 689 corresponds to the bottom or distal end of the terminal 214′″. The pin 689 is configured to be received by a socket coupled to the system substrate 201.

Regardless of the type of terminal used in device 110, 210, and as will be discussed in more detail below, each terminal (and particularly each of terminals 115, 116, 215, 216) has a non-negligible inductance between its proximal and distal ends, which corresponds to a non-negligible series inductance of an impedance matching circuit (e.g., circuit 150, 160, 171, 172).

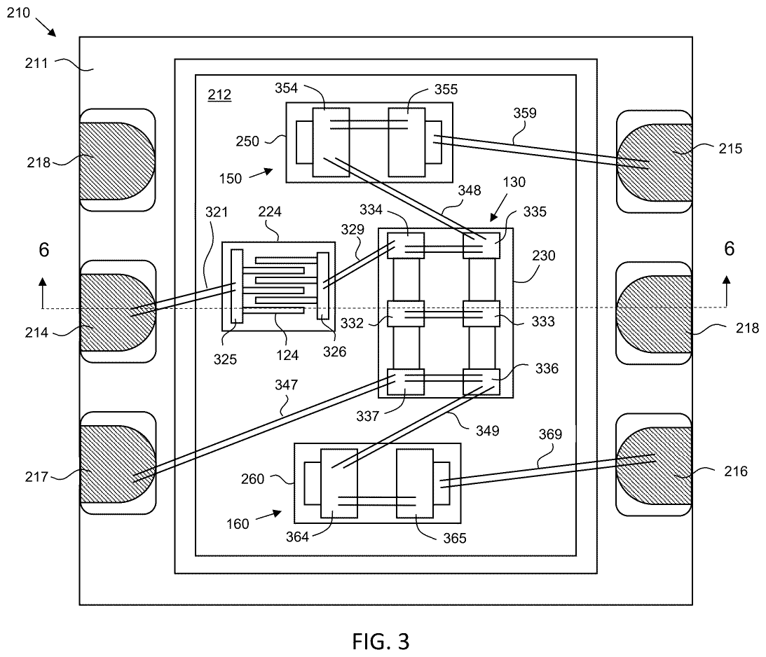

The circuitry of amplifier system 100, 200 will now be discussed in greater detail in conjunction with FIGS. 1-3, where FIG. 3 is an enlarged, top view of the driver amplifier and splitter device 210 shown in FIG. 2, in accordance with one or more example embodiments. As shown in FIGS. 1 and 2, the system input terminal 104, 204 is electrically coupled to a device input terminal 114, 214 of the driver amplifier and splitter device 110, 210 through a first trace 205 (e.g., transmission line) on the system substrate 101, 201.

The driver amplifier and splitter device 110, 210 is coupled to the mounting surface 202 of the system substrate 101, 201, as mentioned earlier. The driver amplifier and splitter device 110, 210 includes a device input terminal 114, 214, a first device output terminal 115, 215, a second device output terminal 116, 216, a device ground terminal 117, 217, and optional “extra” terminals 218, all of which are physically coupled to the package body 211 as indicated previously. In addition, the driver amplifier and splitter device 110, 210 includes a first power amplifier in the form of a first power transistor 124, a power splitter circuit 130, a first impedance matching circuit 150, and a second impedance matching circuit 160, all physically coupled to the package body 211.

The first power transistor 124 may be integrally formed in a power transistor die 224. The first power transistor 124 may be a field effect transistor (FET), for example, which includes a gate terminal 125 (“transistor input terminal”), a drain terminal 126 (a “transistor output terminal” or a “transistor first current conducting terminal”), and a source terminal 127 (a “transistor second current conducting terminal”). In the power transistor die 224, the gate terminal 125 of the power transistor 124 is electrically coupled to a transistor die input terminal 325 (e.g., a bondpad at the top surface of the die 224), the drain terminal 126 is electrically coupled to a transistor die output terminal 326 (e.g., another bondpad at the top surface of the die 224), and the source terminal 127 may be electrically coupled to a conductive layer (e.g., layer 678, FIG. 6) at the bottom surface of the die 224. As best seen in FIG. 6, the conductive layer 678 of the power transistor die 224 is connected to the device flange 212, according to an embodiment.

According to one or more embodiments, the device input terminal 114, 214 is electrically coupled to the transistor die input terminal 325 (and thus to the gate terminal 125) through an inductance 121, which may be physically implemented as a wirebond set 321 (FIG. 3). As used herein, the term “wirebond set” means one or more wirebonds (e.g., a single wirebond or an array of multiple parallel-coupled wirebonds). The first power transistor 124 is configured to receive an input signal from the system input terminal 104, 204 through the first trace 205, the device input terminal 114, 214, the inductance 121 (wirebond set 321), the transistor die input terminal 325, and the gate terminal 125, and the first power transistor 124 is configured to amplify the input signal and to produce an amplified input signal at the drain terminal 126 and the transistor die output terminal 326. Accordingly, the first power transistor 124 may function as a first amplification stage (e.g., a driver amplifier) for the system 100, 200.

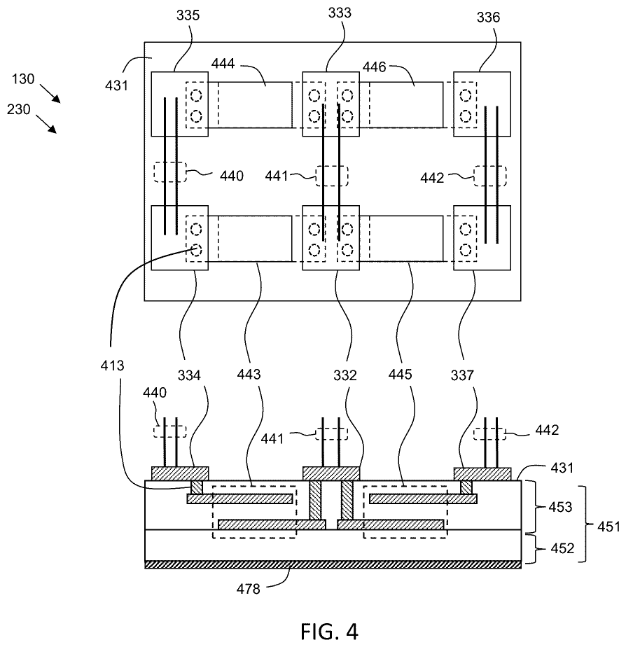

The drain terminal 126 of the first power transistor 124 is electrically coupled through the transistor die output terminal 326 and another inductance 129 (e.g., wirebond set 329, FIG. 3) to the power splitter circuit 130. According to one or more embodiments, the power splitter circuit 130 is housed in a first passive device assembly 230 (“first PDA”), and FIG. 4 includes enlarged top and side, cross-sectional views of the first PDA 230, in accordance with one or more example embodiments.

According to one or more embodiments, the first PDA 230 is an integrated passive device (IPD), which includes a plurality of splitter components integrated within and/or coupled to a semiconductor substrate 451 (FIG. 4). The semiconductor substrate 451 more specifically includes a base semiconductor substrate 452 (e.g., including silicon, silicon carbide, silicon germanium, or other semiconductor materials), and a build-up structure 453 on top of the base semiconductor substrate 452. The build-up structure 453 includes a plurality of patterned conductive layers interleaved with one or more dielectric layers. According to one or more other embodiments, the first PDA 230 may include a different type of substrate, such as a small PCB, a ceramic substrate, or another suitable type of substrate. A conductive layer 478 on the bottom of the first PDA 230 may be used to physically couple the first PDA 230 to the flange 212.

Either way, the power splitter circuit 130 includes a splitter input terminal 134 (e.g., a first bondpad 334 at the top surface of PDA 230), a first splitter output terminal 135 (e.g., a second bondpad 335 at the top surface of PDA 230), a second splitter output terminal 136 (e.g., a third bondpad 336 at the top surface of PDA 230), and a splitter ground terminal 137 (e.g., a fourth bondpad 337 at the top surface of PDA 230). The splitter input terminal 134 is electrically coupled through inductance 129 (e.g., wirebond set 329) to the transistor die output terminal 326, as mentioned above. The splitter ground terminal 137 is electrically coupled through inductance 147 (e.g., wirebond set 347) to the device ground terminal 117, 217, which in turn is coupled to a ground reference node in the system substrate 101, 201.

In addition to terminals 134-137 (bondpads 334-337), the power splitter circuit 130 also includes a plurality of splitter components integrally-formed within the first PDA 230 and electrically coupled between the splitter input terminal 134, the first and second splitter output terminals 135, 136, and the splitter ground terminal 137 (e.g., electrically coupled between bondpads 334-337). According to one or more embodiments, the power splitter circuit 130 more specifically includes first, second, and third inductances 140, 141, 142, first, second, third, and fourth capacitors 143, 144, 145, 146, and first and second intermediate splitter nodes 132, 133 (e.g., fifth and sixth bondpads 332, 333 at the top surface of PDA 230). For example, each of the first, second, and third inductances 140-142 may have an inductance value in a range of about 1 nanohenry (nH) to about 5 nH, although the inductance values may be lower or higher, as well. Each of the first, second, third, and fourth capacitors 143-146 may have a capacitance value in a range of about 0.2 picofarads (pF) to about 5 pF, although the capacitance values may be lower or higher, as well.

Referring to the schematic in FIG. 1, the first inductance 140 is coupled between the splitter input terminal 134 and the first splitter output terminal 135, the first capacitor 143 is coupled between the splitter input terminal 134 and the first intermediate splitter node 132, the second capacitor 144 is coupled between the first splitter output terminal 135 and the second intermediate splitter node 133, the second inductance 141 is coupled between the first and second intermediate splitter nodes 132, 133, the third capacitor 145 is coupled between the first intermediate node 132 and the splitter ground terminal 137, the fourth capacitor 146 is coupled between the second intermediate node 133 and the second splitter output terminal 136, and the third inductance 142 is coupled between the splitter ground terminal 137 and the second splitter output terminal 136.

Referring to the first PDA 230 in FIGS. 3 and 4, the first, second, and third inductances 140-142 may be implemented as first, second, and third wirebond sets 440, 441, 442, according to one or more embodiments. According to one or more alternate embodiments, each of the first, second, and third inductances 140-142 alternatively may be implemented as a spiral inductor integrated within the first PDA 230 or as a discrete, surface-mount inductor coupled to the top surface of the first PDA 230.

The first, second, third, and fourth capacitors 143-146 may be implemented as first, second, third, and fourth integrated capacitors 443, 444, 445, 446 within the semiconductor substrate 451 (or more specifically within the build-up structure 453) of the first PDA 230. For example, each of the first, second, third, and fourth integrated capacitors 443-446 may be a metal-insulator-metal (MIM) capacitor that includes a first electrode formed from a portion of a first conductive layer of the build-up structure 453, a second electrode aligned with the first electrode and formed from a portion of a second conductive layer of the build-up structure 453, and dielectric material between the first and second electrodes. The electrodes of the first, second, third, and fourth integrated capacitors 443, 444, 445, 446 may be electrically coupled to one of the splitter terminals or intermediate nodes (e.g., bondpads 332-337) through conductive vias (e.g., vias 413) in the build-up structure 453. According to one or more alternate embodiments, each of the first, second, third, and fourth capacitors 143-146 may be implemented as a discrete, surface-mount capacitor coupled to the top surface of the first PDA 230.

As mentioned above, the drain terminal 126 of the first power transistor 124 is electrically coupled through the transistor die output terminal 326 and another inductance 129 (e.g., wirebond set 329, FIG. 3) to the power splitter circuit 130. More specifically, the inductance 129 (e.g., wirebond set 329) is electrically coupled to the splitter input terminal 134 (first bondpad 334). According to one or more embodiments, the power splitter circuit 130 is configured to receive the amplified input signal through the splitter input terminal 134 (first bondpad 334) and to divide a power of the amplified input signal to produce a first splitter output signal at the first splitter output terminal 135 (second bondpad 335) and to produce a second splitter output signal at the second splitter output terminal 136 (third bondpad 336). As will be discussed in more detail below, the first splitter output signal corresponds to a signal that will be further amplified through a first amplifier path (e.g., carrier amplifier path 180), and the second splitter output signal corresponds to a signal that will be further amplified through a second amplifier path (e.g., peaking amplifier path 190). Accordingly, the first and second splitter output terminals 135, 136 (or the second and third bondpads 335, 336) may be considered to be the inputs to the first and second amplifier paths, respectively.

According to one or more embodiments, the power splitter circuit 130 may be a quadrature hybrid splitter, which is configured to produce the first and second splitter output signals at the first and second splitter output terminals 135, 136 (at bondpads 335, 336) with a phase difference of about 90 degrees. The 90 degree phase shift is provided to account for a phase shift applied along the first amplification path 180 by the phase shift and impedance inversion circuit 187, 287, as discussed later. According to an alternate embodiment, the power splitter circuit 130 may be another type of splitter (e.g., a Wilkinson power splitter), which produces first and second splitter output signals that do not have a phase difference, and a phase difference between the first and second splitter output signals may be imparted after the second splitter output terminal 136 by a distinct phase shift element (not illustrated).

Referring again to FIGS. 1 and 3, the first splitter output terminal 135 (e.g., bondpad 335) is directly electrically connected to the first device output terminal 115, 215 through a first impedance matching circuit 150, and the second splitter output terminal 136 (e.g., bondpad 336) is directly electrically connected to the second device output terminal 116, 216 through a second impedance matching circuit 160. As discussed elsewhere herein, the first impedance matching circuits 150, 160 correspond to first stages of interstage matching networks 171, 172, which are implemented wholly within the driver amplifier and splitter device 210.

The first and second impedance matching circuits 150, 160 may have the same circuit topology, as shown in FIGS. 1 and 3, or alternatively the first and second impedance matching circuits 150, 160 may have different circuit topologies. Referring to the schematic in FIG. 1, the first impedance matching circuit 150 includes a first inductance 148 coupled between the first splitter output terminal 135 and a first intermediate node 154, a first shunt capacitor 157 coupled between the first intermediate node 154 and a ground reference node, a second inductance 156 coupled between the first intermediate node 154 and a second intermediate node 155, a second shunt capacitor 158 coupled between the second intermediate node 155 and the ground reference node, and a third inductance 159 coupled between the second intermediate node 155 and the first device output terminal 115. For example, the inductance values of each of the first, second, and third inductances 148, 156, 159 may be in a range of about 0.5 nH to about 4 nH, and the capacitance values of each of the first and second shunt capacitors 157, 158 may be in a range of about 0.5 pF to about 6 pF, although the inductance and capacitance values may be lower or higher, as well. According to an embodiment, the first device output terminal 115 is characterized by a non-negligible inductance, which also is considered to be part of the first impedance matching circuit 150. For example, the inductance value of the first device output terminal 115 may be in a range of about 1 nH to about 10 nH, although the inductance value may be lower or higher, as well. According to one or more embodiments, the impedance transformation provided by the first impedance matching network 150 is a transformation of at least 10 ohms.

Similarly, the second impedance matching circuit 160 includes a first inductance 149 coupled between the second splitter output terminal 136 and a first intermediate node 164, a first shunt capacitor 167 coupled between the first intermediate node 164 and the ground reference node, a second inductance 166 coupled between the first intermediate node 164 and a second intermediate node 165, a second shunt capacitor 168 coupled between the second intermediate node 165 and the ground reference node, and a third inductance 169 coupled between the second intermediate node 165 and the second device output terminal 116. The inductance and capacitance values of inductances 149, 166, 169 and capacitors 167, 168 may be approximately the same as the corresponding inductances 148, 156, 159 and capacitors 157, 158 in the first impedance matching circuit 150. According to an embodiment, the second device output terminal 116 also is characterized by a non-negligible inductance, which also is considered to be part of the second impedance matching circuit 160. For example, the inductance of the second device output terminal 116 may be in a range of about 1 nH to about 10 nH, although the inductance value may be lower or higher, as well. According to one or more embodiments, the impedance transformation provided by the second impedance matching network 160 is a transformation of at least 20 ohms.

As shown in FIG. 3, according to one or more embodiments, some portions of the first impedance matching circuit 150, and specifically the first and third inductances 148, 159, are provided by first and second wirebond sets 348, 359. As will be described in more detail later, another portion of the first impedance matching circuit 150 is housed in a second passive device assembly 250 (“second PDA”). The first wirebond set 348 (e.g., first inductance 148) is coupled between the first splitter output terminal 135, 335 and the first intermediate node 154 (e.g., a first bondpad 354 of PDA 250), and the second wirebond set 359 (e.g., third inductance 159) is coupled between the second intermediate node 155 (e.g., a second bondpad 355 of PDA 250) and the first device output terminal 115, 215.

Similarly, some portions of the second impedance matching circuit 160, and specifically the first and third inductances 149, 169, are provided by first and second wirebond sets 349, 369. Another portion of the second impedance matching circuit 160 is housed in a third passive device assembly 260 (“third PDA”). The first wirebond set 349 (e.g., first inductance 149) is coupled between the second splitter output terminal 136, 336 and the first intermediate node 164 (e.g., a first bondpad 364 of PDA 260), and the second wirebond set 369 (e.g., third inductance 169) is coupled between the second intermediate node 165 (e.g., a second bondpad 365 of PDA 260) and the second device output terminal 116, 216.

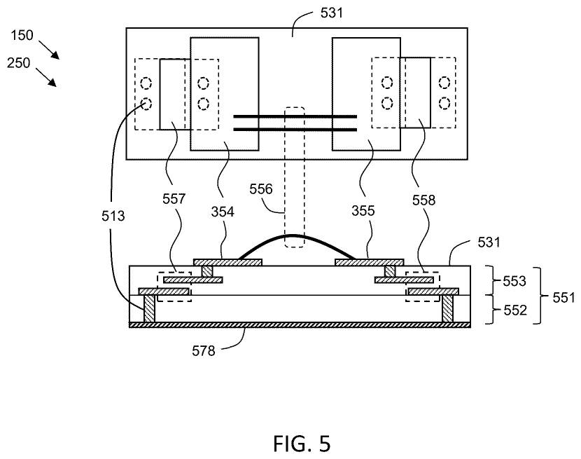

FIG. 5 includes enlarged top and side, cross-sectional views of the second PDA 250, in accordance with one or more example embodiments. Assuming that the first and second impedance matching circuits 150, 160 have the same circuit topology, the third PDA 260 may have an identical structure to the second PDA 250. For purposes of brevity, enlarged views of the third PDA 260 are not included herein. The second and third PDAs 250, 260 will be generically referred to as an “impedance matching PDA.”

According to one or more embodiments, the impedance matching PDA 250 is an IPD, which includes a plurality of impedance matching components integrated within and/or coupled to a semiconductor substrate 551 (FIG. 5). For example, the first and second intermediate nodes 154, 155 may be implemented as bondpads 354, 355 at the top surface of the impedance matching PDA 250, and the first and second shunt capacitors 157, 158 may be implemented as integrated capacitors within the impedance matching PDA 250, as will be described in more detail below.

The semiconductor substrate 551 more specifically includes a base semiconductor substrate 552 (e.g., including silicon, silicon carbide, silicon germanium, or other semiconductor materials), and a build-up structure 553 on top of the base semiconductor substrate 552. The build-up structure 553 includes a plurality of patterned conductive layers interleaved with one or more dielectric layers. According to one or more other embodiments, the impedance matching PDA 250 may include a different type of substrate, such as a small PCB, a ceramic substrate, or another suitable type of substrate. A conductive layer 578 on the bottom of the impedance matching PDA 250 may be used to physically couple the impedance matching PDA 250 to the flange 212.

The second inductance 156 may be implemented as a wirebond set 556 coupled between the first and second intermediate nodes (e.g., bondpads 354, 355), according to one or more embodiments. According to one or more alternate embodiments, the second inductance 156 alternatively may be implemented as a spiral inductor integrated within the impedance matching PDA 250 or as a discrete, surface-mount inductor coupled to the top surface of the impedance matching PDA 250.

As mentioned above, the first and second shunt capacitors 157, 158 may be implemented as first and second integrated capacitors 557, 558 within the semiconductor substrate 551 (or more specifically within the build-up structure 553) of the impedance matching PDA 250. For example, each of the first and second integrated capacitors 557, 558 may be a MIM capacitor that includes a first electrode formed from a portion of a first conductive layer of the build-up structure 553, a second electrode aligned with the first electrode and formed from a portion of a second conductive layer of the build-up structure 553, and dielectric material between the first and second electrodes. The first electrodes of the first and second integrated capacitors 557, 558 may be electrically coupled to the first or second intermediate nodes (e.g., bondpads 354, 355) through conductive vias (not numbered) in the build-up structure 553. The second electrodes of the first and second integrated capacitors 557, 558 may be electrically coupled to the ground reference node (e.g., conductive layer 578) through additional conductive vias (e.g., vias 513), which extend through the base semiconductor substrate 552. According to one or more alternate embodiments, each of the first and second capacitors 557, 558 may be implemented as a discrete, surface-mount capacitor coupled to the top surface of the impedance matching PDA 250.

FIGS. 2 and 3 illustrate embodiments in which the splitter circuit 130 and portions of the first and second impedance matching circuits 150, 160 (specifically capacitors 157, 158, 167, 168 and inductors 156, 166) are implemented with three separate PDAs 230, 250, 260 that are coupled to the package body 211 (or more specifically, to the flange 212). According to one or more other embodiments, more or fewer PDAs may be used for these components. For example, as few as one PDA may be used to house the components of the splitter circuit 130 and the portions of the first and second impedance matching circuits 150, 160 (in which case, inductors 148, 149, 348, 349 also may be integrated into or onto the single PDA). Alternatively, two PDAs could be used, where one PDA houses the components for the splitter circuit 130, and a second PDA houses the portions of the first and second impedance matching circuits 150, 160. Other combinations also are possible.

In some embodiments, as shown in FIG. 6, the power transistor die 224, the one or more PDAs 230, 250, 260, the various wirebond sets (e.g., wirebond sets 321, 329, 347, 348, 359, 369), the top surface of the lower package body 211, and portions of the top surfaces (or internal or proximal ends) of the terminals 214-218 may be overmolded with encapsulant material 610. Alternatively, a protective cap may be attached to the top surface of the lower package body 211 to establish a sealed, internal air cavity (indicated by the dashed box in FIG. 6) that contains the power transistor die 224, the one or more PDAs 230, 250, 260, and the various wirebond sets. In other words, the packaged amplifier device 210 also may be an air-cavity DFN package (or another type of surface-mount, air cavity package).

Referring again to FIGS. 1 and 2, amplifier 100, 200 also may include first and second bias circuits 122, 123 (BIAS CKT) configured to provide gate and drain bias voltages, respectfully, to the first power transistor 124. The gate bias circuit 122 may be electrically coupled to the device input terminal 114, 214, for example, and the drain bias circuit 123 may be electrically coupled to one of the device output terminals 115, 215 or 116, 216. The gate bias circuit 122 may receive a gate bias voltage from an external power supply, and may provide the gate bias voltage to the gate terminal 125, 325 of the first power transistor through the device input terminal 114, 214. Similarly, the drain bias circuit 123 may receive a drain bias voltage from an external power supply, and may provide the drain bias voltage to the drain terminal 126, 326 of the first power transistor through the first or second device output terminal 115, 116, 215, 216. In other embodiments, the gate and/or drain bias voltages may be provided to the first power transistor 124 through other terminals (e.g., extra terminals 218).

As mentioned above, the power transistor 124 within the driver amplifier and splitter device 110, 210 corresponds to a first amplification stage (e.g., a driver amplification stage) in the multiple-stage, multiple-path amplifier 100, 200. Additionally, as discussed above, the first impedance matching circuits 150, 160 correspond to first stages of interstage matching networks 171, 172 between the first amplification stage and subsequent amplification stages. With continued reference to FIGS. 1 and 2, the additional interstage impedance matching and amplification stage(s) will now be explained.

As shown in FIGS. 1 and 2 and discussed earlier, the driver amplifier and splitter device 110, 210 is coupled to the mounting surface 202 of the system substrate 101, 201, and specifically, the first and second device output terminals 115, 116, 215, 216 are physically and electrically coupled to first ends of second and third traces 107, 108, 207, 208 (e.g., transmission lines) on the system substrate 101, 201. According to one or more embodiments, the final stage amplifier device 170, 270 is a SMD that also is coupled to the mounting surface 202 of the system substrate 101, 201. Specifically, terminals 174, 175, 274, 275 of device 170, 270 are physically and electrically coupled to second ends of the second and third traces 107, 108, 207, 208.

According to one or more embodiments, the series inductances of the second and third traces 107, 108, 207, 208 provide second stages of the first and second interstage matching networks 171, 172. The electrical lengths and other characteristics of the second and third traces 107, 108, 207, 208 may be selected so that the second and third traces 107, 108, 207, 208 provide a desired series inductance in each of the first and second interstage matching networks 171, 172. According to one or more embodiments, the inductance value of each of the second and third traces 107, 108, 207, 208 may be in a range of about 1 nH to about 10 nH, although the inductance values may be lower or higher, as well. In some scenarios, such as those illustrated in FIGS. 1 and 2, the second and third traces 107, 108, 207, 208 may be the only components of the second stages of the first and second interstage matching networks 171, 172. In other scenarios, it may be desirable to include additional components to the second stages of the first and second interstage matching networks 171, 172 (e.g., additional series and/or shunt inductances and/or capacitances). Either way, the second stages of the first and second interstage matching networks 171, 172 on the system substrate 101, 201 may be simplified, in comparison with conventional multi-stage amplifiers, since other portions of the first and second interstage matching networks 171, 172 (e.g., the first and third stages) are implemented in the driver amplifier and splitter device 110, 210 and in the final stage amplifier device 170, 270.

The final stage amplifier device 170, 270 includes a first device input terminal 174, 274, a second device input terminal 175, 275, a first device output terminal 276, and a second device output terminal 277, all of which are physically coupled to a package body (not numbered). For reasons explained below, the first and second device output terminals are not depicted in FIG. 1. In addition, the final stage amplifier device 170, 270 also includes additional portions of the first and second amplifier paths 180, 190 (including third stages of the first and second interstage matching networks 171, 172). More specifically, within device 170, 270, additional portions of the first amplification path 180 are coupled between the first device input terminal 174, 274 and the first device output terminal 276. These additional portions include an in-package impedance matching network 181 (IN-PKG IMN), a second power transistor 182, and all or portions of a first output matching network 186 (OMN). Similarly, additional portions of the second amplification path 190 are coupled between the second device input terminal 175, 275 and the second device output terminal 277. These additional portions include an in-package impedance matching network 191 (IN-PKG IMN), a third power transistor 192, and all or portions of a second output matching network 196 (OMN).

According to one or more embodiments, the first device input terminal 174, 274 is electrically coupled to the second power transistor 182 through the in-package impedance matching network 181. Similarly, the second device input terminal 175, 275 is electrically coupled to the third power transistor 192 through the in-package impedance matching network 191. Each of the first and second in-package impedance matching networks 181, 191 may include a network of inductances and capacitances that are selected to provide a desired impedance transformation between the first and second device input terminals 174, 175, 274, 275 and the second and third transistor input terminals 183, 193. For example, the first and second in-package impedance matching networks 181, 191 may include one or more T-matching networks, PI-matching networks, and/or other impedance matching network topologies.

As indicated above, the first and second in-package impedance matching networks 181, 191 provide the third (final) stage of the first and second interstage matching circuits 171, 172. The third stage of the first and second interstage matching circuits 171, 172 also includes non-negligible inductances of the first and second device input terminals 174, 175, 274, 275. For example, the inductance value of each of the first and second device input terminals 174, 175, 274, 275 may be in a range of about 1 nH to about 10 nH, although the inductance value may be lower or higher, as well.

As a recap, the complete first interstage matching circuit 171 includes the first impedance matching circuit 150 (including the series inductance of terminal 115, 215), the inductance of trace 107, 207, the series inductance of terminal 174, 274, and the first in-package matching network 181. The complete second interstage matching circuit 172 includes the second impedance matching circuit 160 (including the series inductance of terminal 116, 216), the inductance of trace 108, 208, the series inductance of terminal 175, 275, and the second in-package matching network 191.

At this point, it may be reiterated that inclusion of the first and second impedance matching circuits 150, 160 within device 110, 210 may provide a specific technical advantage, in that this integration may simplify the design for the rest of the interstage impedance matching between the first and second splitter output terminals 135, 136, 335, 336 and the gate terminals 183, 193 of the second-stage power transistors 182, 192. More specifically, amplifier 100, 200 can be designed so that the second stage of the interstage matching provided on the system substrate 101, 201 may be as simple as providing the second and third traces 107, 108. Accordingly, amplifier development time and cost may be reduced, and more compact amplifier designs may be achieved.

Each of the second and third power transistors 182, 192 may be integrally formed in a power transistor die (not shown). The second and third power transistors 182, 192 may be FETs, for example, and each may include a gate terminal 183, 193 (“transistor input terminal”), a drain terminal 184, 194 (a “transistor output terminal” or a “transistor first current conducting terminal”), and a source terminal 185, 195 (a “transistor second current conducting terminal”). The source terminals 185, 195 may be electrically coupled to a ground reference node.

As indicated above, and according to one or more embodiments, the first device input terminal 174, 274 is electrically coupled to the second power transistor gate terminal 183 through the first in-package impedance matching network 181. Similarly, the second device input terminal 175, 275 is electrically coupled to the third power transistor gate terminal 193 through the second in-package impedance matching network 191.

The second and third power transistors 182, 192 are configured to receive the first and second amplified input signals from the first and second device input terminals 174, 175, 274, 275. The second power transistor 182 is configured to further amplify the first amplified input signal and to produce a first amplified output signal at the drain terminal 184. Accordingly, the second power transistor 182 may function as a second amplification stage (e.g., a final amplifier) along the first amplification path 180. Similarly, the third power transistor 192 is configured to further amplify the second amplified input signal and to produce a second amplified output signal at the drain terminal 194. Accordingly, the third power transistor 192 may function as a second amplification stage (e.g., a final amplifier) along the second amplification path 190.

Although not shown in FIG. 1 or 2, amplifier 100, 200 also may include additional bias circuits configured to provide gate and drain bias voltages, respectfully, to the second and third power transistors 182, 192. These bias voltages help to establish the correct operating conditions to bias the second power transistor 182 to operate in class AB mode, and to bias the third power transistor 192 to operate in class C mode, as is appropriate for proper Doherty amplifier operation (i.e., the second power transistor 182 is biased to operate as a carrier amplifier, and the third power transistor 192 is biased to operate as a peaking amplifier).

Along the first amplification path 180, the drain terminal 184 of the second power transistor 182 is electrically coupled through a first output matching network 186 (OMN), a first device output terminal 276, and a phase shift and impedance inversion circuit 187, 287 to the combining node 188, 288. Note that the first device output terminal 276 is not depicted in FIG. 1 to illustrate the point that some portions of the first output matching network 186 may be implemented within the final stage amplifier device 170, 270, while other portions of the first output matching network 186 may be implemented on the system substrate 101, 201. Regardless, the first output matching network 186 is configured to perform an impedance transformation between the drain terminal 184 and the phase shift and impedance inversion circuit 187, 287.

The phase shift and impedance inversion circuit 187, 287 is configured to apply a phase shift (e.g., typically between about 70 degrees and about 90 degrees) to the amplified signal conveyed along the first amplification path 180, and also to provide an impedance inversion. The phase shift should be designed so that the first and second amplified output signals produced by the second and third power transistors 182, 192 arrive in phase at the combining node 188.

Along the second amplification path 190, the drain terminal 194 of the third power transistor 192 is electrically coupled through a second output matching network 196 (OMN) and a second device output terminal 277 to the combining node 188, 288. Again, note that the second device output terminal 277 is not depicted in FIG. 1 to illustrate the point that some portions of the second output matching network 196 may be implemented within the final stage amplifier device 170, 270, while other portions of the second output matching network 196 may be implemented on the system substrate 101, 201. Regardless, the second output matching network 196 is configured to perform an impedance transformation between the drain terminal 194 and the combining node 188, 288.

The further amplified first and second signals produced by the first and second amplification paths 180, 190 are combined (in phase) at the combining node 188, 288. The combined amplified signal is then conveyed through the output impedance transformer circuit 197, 297 to the system output terminal 106, 206.

As a short recap, the first amplifier path 180 (e.g., the carrier amplifier path) includes substantially all of the circuitry between the first splitter output terminal 135, 235 and the combining node 188, 288, and the second amplifier path 190 (e.g., the peaking amplifier path) includes substantially all of the circuitry between the second splitter output terminal 136, 236 and the combining node 188, 288. More specifically, the first amplifier path 180 includes the first interstage matching circuit 171, power transistor 182, output impedance matching network 186, and phase shift and impedance inversion circuit 187. The second amplifier path 190 includes the second interstage matching circuit 172, power transistor 192, and output impedance matching network 196.

One or more embodiments of a packaged amplifier device 110, 210 include a package body 211, 212, a device input terminal 214, a first device output terminal 215, and a second device output terminal 216, all coupled to the package body. The packaged amplifier device also includes a power amplifier die 224, one or more passive device assemblies 230, 250, 260, a power splitter circuit 130, a first impedance matching circuit 150, and a second impedance matching circuit 160.

The power amplifier die is physically coupled to the package body, and the power amplifier die has an integrated power transistor 124, a transistor input terminal 325 electrically coupled to the device input terminal 214, and a transistor output terminal 326. The integrated power transistor is configured to receive an input signal through the transistor input terminal and to produce an amplified input signal at the transistor output terminal.

The one or more passive device assemblies 230, 250, 260 also are physically coupled to the package body, and the power splitter circuit 130 is physically coupled to the one or more passive device assemblies. The power splitter circuit includes a splitter input terminal 334 electrically coupled to the transistor output terminal, a first splitter output terminal 335, a second splitter output terminal 336, and a plurality of splitter components 440-442, 443-446 electrically coupled between the splitter input terminal, the first splitter output terminal, and the second splitter output terminal. The plurality of splitter components is configured to receive the amplified input signal through the splitter input terminal and to divide a power of the amplified input signal to produce a first splitter output signal at the first splitter output terminal and to produce a second splitter output signal at the second splitter output terminal.

The first impedance matching circuit 150 also is physically coupled to the one or more passive device assemblies. The first impedance matching circuit is directly connected to the first splitter output terminal and to the first device output terminal, and the first impedance matching circuit is configured to convey the first splitter output signal from the first splitter output terminal to the first device output terminal while performing a first impedance transformation between the first splitter output terminal and the first device output terminal. The second impedance matching circuit 160 also is physically coupled to the one or more passive device assemblies. The second impedance matching circuit is directly connected to the second splitter output terminal and to the second device output terminal, and the second impedance matching circuit is configured to convey the second splitter output signal from the second splitter output terminal to the second device output terminal while performing a second impedance transformation between the second splitter output terminal and the second device output terminal.

One or more embodiments of a multiple-stage, multiple-path power amplifier 100, 200 include a system substrate 101, 201 with a mounting surface 202, a system input terminal 104, 204 coupled to the system substrate, a system output terminal 106, 206 coupled to the system substrate, and a first packaged amplifier device 110, 210 coupled to the mounting surface of the system substrate.

The first packaged amplifier device includes a package body 211, a first device input terminal 114, 214 physically coupled to the package body and electrically coupled to the system input terminal, a first device output terminal 115, 215 physically coupled to the package body, and a second device output terminal 116, 216 physically coupled to the package body. The amplifier also includes a first power amplifier physically coupled to the package body, which includes a first transistor 124, a first transistor input terminal 125, 325 electrically coupled to the first device input terminal, and a first transistor output terminal 126, 326. A power splitter circuit 130, 230 also is physically coupled to the package body and the power splitter circuit includes a splitter input terminal 134, 334 electrically coupled to the first transistor output terminal, a first splitter output terminal 135, 335, and a second splitter output terminal 136, 336. A first impedance matching circuit 150 is physically coupled to the package body and is directly connected to the first splitter output terminal and to the first device output terminal. A second impedance matching circuit 160 also is physically coupled to the package body and is directly connected to the second splitter output terminal and to the second device output terminal.

The multiple-stage, multiple-path power amplifier also includes a second power amplifier coupled to the system substrate, and the second power amplifier includes a second transistor 182 with a second transistor input terminal 183 and a second transistor output terminal 184. A first transmission line 107, 207 also is coupled to the system substrate, and the first transmission line is electrically coupled between the first device output terminal and the second transistor input terminal. A third power amplifier also is coupled to the system substrate, and the third power amplifier includes a third transistor 192 with a third transistor input terminal 193 and a third transistor output terminal 194. Finally, a second transmission line 108, 208 also is coupled to the system substrate, and the second transmission line is electrically coupled between the second device output terminal and the third transistor input terminal.

The preceding detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first,” “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A packaged amplifier device comprising:
a package body;
a device input terminal, a first device output terminal, and a second device output terminal all coupled to the package body;
a power amplifier die physically coupled to the package body, wherein the power amplifier die has an integrated power transistor, a transistor input terminal electrically coupled to the device input terminal, and a transistor output terminal, and wherein the integrated power transistor is configured to receive an input signal through the transistor input terminal and to produce an amplified input signal at the transistor output terminal;
one or more passive device assemblies physically coupled to the package body;
a power splitter circuit physically coupled to the one or more passive device assemblies, wherein the power splitter circuit includes a splitter input terminal electrically coupled to the transistor output terminal, a first splitter output terminal, a second splitter output terminal, and a plurality of splitter components electrically coupled between the splitter input terminal, the first splitter output terminal, and the second splitter output terminal, wherein the plurality of splitter components is configured to receive the amplified input signal through the splitter input terminal and to divide a power of the amplified input signal to produce a first splitter output signal at the first splitter output terminal and to produce a second splitter output signal at the second splitter output terminal;
a first impedance matching circuit physically coupled to the one or more passive device assemblies, wherein the first impedance matching circuit is directly connected to the first splitter output terminal and to the first device output terminal, and wherein the first impedance matching circuit is configured to convey the first splitter output signal from the first splitter output terminal to the first device output terminal while performing a first impedance transformation between the first splitter output terminal and the first device output terminal; and
a second impedance matching circuit physically coupled to the one or more passive device assemblies, wherein the second impedance matching circuit is directly connected to the second splitter output terminal and to the second device output terminal, and wherein the second impedance matching circuit is configured to convey the second splitter output signal from the second splitter output terminal to the second device output terminal while performing a second impedance transformation between the second splitter output terminal and the second device output terminal.

2. The packaged amplifier device of claim 1, wherein the power splitter circuit is configured to produce the first and second splitter output signals at the first and second splitter output terminals with a phase difference of 90 degrees.

3. The packaged amplifier device of claim 1, wherein the one or more passive device assemblies include:
a first passive device assembly that houses the power splitter circuit;
a second passive device assembly that houses a portion of the first impedance matching circuit; and
a third passive device assembly that houses a portion of the second impedance matching circuit.

4. The packaged amplifier device of claim 1, wherein the plurality of splitter components includes:
first, second, and third inductances;
first, second, third, and fourth capacitors; and
first and second intermediate splitter nodes, wherein
the first inductance is coupled between the splitter input terminal and the first splitter output terminal,
the first capacitor is coupled between the splitter input terminal and the first intermediate splitter node,
the second capacitor is coupled between the first splitter output terminal and the second intermediate splitter node,
the second inductance is coupled between the first and second intermediate splitter nodes,
the third capacitor is coupled between the first intermediate node and a splitter ground terminal,
the fourth capacitor is coupled between the second intermediate node and the second splitter output terminal, and
the third inductance is coupled between the splitter ground terminal and the second splitter output terminal.

5. The packaged amplifier device of claim 4, wherein:
the one or more passive device assemblies includes an integrated passive device that includes a semiconductor substrate and houses the power splitter circuit;
the first and second intermediate splitter nodes include first and second bondpads, respectively;
the first, second, and third inductances include a first wirebond set, a second wirebond set, and a third wirebond set, respectively, coupled to an upper surface of the integrated passive device; and
the first, second, third, and fourth capacitors include a first integrated capacitor, a second integrated capacitor, a third integrated capacitor, and a fourth integrated capacitor.

6. The packaged amplifier device of claim 4, wherein:
the power splitter circuit further includes the splitter ground terminal; and
the packaged amplifier device further comprises
a device ground terminal physically coupled to the package body, and electrically coupled to the splitter ground terminal.

7. The packaged amplifier device of claim 1, wherein the first impedance matching circuit comprises:
first, second, and third inductances;
first and second shunt capacitors; and
first and second intermediate splitter nodes, wherein
the first inductance is coupled to the first splitter output terminal and to the first intermediate splitter node,
the first shunt capacitor is coupled between the first intermediate splitter node and a ground reference node,
the second inductance is coupled between the first and second intermediate splitter nodes,
the second shunt capacitor is coupled between the second intermediate splitter node and the ground reference node, and
the third inductance is coupled to the second intermediate splitter node and connected to the first device output terminal.

8. The packaged amplifier device of claim 7, wherein:
the one or more passive device assemblies includes an integrated passive device that includes a semiconductor substrate and houses a portion of the first impedance matching circuit;
the first and second intermediate splitter nodes include first and second bondpads, respectively;
the first inductance includes a first wirebond set coupled between the first splitter output terminal and the first bondpad;
the second inductance includes a second wirebond set coupled to an upper surface of the integrated passive device between the first and second bondpads;
the third inductance includes a third wirebond set coupled between the second bondpad and the first device output terminal;
the first and second capacitors include a first integrated capacitor and a second integrated capacitor.

9. The packaged amplifier device of claim 7, wherein the first impedance matching circuit further includes a fourth inductance corresponding to an inductance of the first device output terminal, and wherein the fourth inductance has an inductance value in a range of 1 nanohenry to 10 nanohenries.

10. The packaged amplifier device of claim 1, wherein:
the first impedance matching circuit is configured to perform the first impedance transformation between the first splitter output terminal and the first device output terminal of at least 10 ohms; and
the second impedance matching circuit is configured to the second impedance transformation between the second splitter output terminal and the second device output terminal of at least 20 ohms.

11. The packaged amplifier device of claim 1, further comprising:
a conductive flange embedded in the package body and having a mounting surface, wherein the power amplifier die and the one or more passive device assemblies are coupled to the mounting surface of the conductive flange.

12. The packaged amplifier device of claim 1, further comprising:
a first wirebond set coupled between the transistor input terminal and the device input terminal; and
a second wirebond set coupled between the transistor output terminal and the splitter input terminal.

13. The packaged amplifier device of claim 1, wherein the packaged amplifier device is a surface mount device, and wherein the device input terminal, the first device output terminal, and the second device output terminal are selected from Dual Flat No-Lead (DFN) package leads, Quad Flat No-Lead (QFN) package leads, gull wing leads, Land Grid Array (LGA) package leads, and Ball Grid Array (BGA) package leads.

14. A multiple-stage, multiple-path power amplifier comprising:
a system substrate with a mounting surface;
a system input terminal coupled to the system substrate;
a system output terminal coupled to the system substrate;
a first packaged amplifier device coupled to the mounting surface of the system substrate, wherein the first packaged amplifier device includes
a package body,
a first device input terminal physically coupled to the package body and electrically coupled to the system input terminal,
a first device output terminal physically coupled to the package body,
a second device output terminal physically coupled to the package body,
a first power amplifier physically coupled to the package body and including a first transistor, a first transistor input terminal electrically coupled to the first device input terminal, and a first transistor output terminal,
a power splitter circuit physically coupled to the package body and including a splitter input terminal electrically coupled to the first transistor output terminal, a first splitter output terminal, and a second splitter output terminal,
a first impedance matching circuit physically coupled to the package body and directly connected to the first splitter output terminal and to the first device output terminal, and
a second impedance matching circuit physically coupled to the package body and directly connected to the second splitter output terminal and to the second device output terminal;
a second power amplifier coupled to the system substrate, wherein the second power amplifier includes a second transistor, a second transistor input terminal, and a second transistor output terminal;
a first transmission line coupled to the system substrate, wherein the first transmission line is electrically coupled between the first device output terminal and the second transistor input terminal;
a third power amplifier coupled to the system substrate, wherein the third power amplifier includes a third transistor, a third transistor input terminal, and a third transistor output terminal; and
a second transmission line coupled to the system substrate, wherein the second transmission line is electrically coupled between the second device output terminal and the third transistor input terminal.

15. The multiple-stage, multiple-path power amplifier of claim 14, wherein:
the first impedance matching circuit and the first transmission line form portions of a first interstage matching network between the first splitter output terminal and the second transistor input terminal; and
the second impedance matching circuit and the second transmission line form portions of a second interstage matching network between the second splitter output terminal and the third transistor input terminal.

16. The multiple-stage, multiple-path power amplifier of claim 14, wherein:
the second and third power amplifiers are housed within a second packaged amplifier device that includes a second device input terminal electrically coupled to the second transistor input terminal, and a third device input terminal electrically coupled to the third transistor input terminal;
the first transmission line has a first end directly connected to the first device output terminal and a second end directly connected to the second device input terminal; and
the second transmission line has a first end directly connected to the second device output terminal and a second end directly connected to the third device input terminal.

17. The multiple-stage, multiple-path power amplifier of claim 16, wherein:
the second packaged amplifier device further includes a first in-package impedance matching network coupled between the second device input terminal and the second transistor input terminal, and a second in-package impedance matching network coupled between the second device input terminal and the second transistor input terminal;
the first impedance matching circuit, the first transmission line, the second device input terminal, and the first in-package impedance matching network form portions of a first interstage matching network between the first splitter output terminal and the second transistor input terminal; and
the second impedance matching circuit, the second transmission line, the third device input terminal, and the second in-package impedance matching network form portions of a second interstage matching network between the second splitter output terminal and the third transistor input terminal.

18. The multiple-stage, multiple-path power amplifier of claim 17, wherein the first packaged amplifier device further comprises:
a power amplifier die physically coupled to the package body, wherein the power amplifier die includes the first transistor, the first transistor input terminal, and the first transistor output terminal, and wherein the first transistor is configured to receive an input signal through the first transistor input terminal and to produce an amplified input signal at the first transistor output terminal;
one or more passive device assemblies physically coupled to the package body and including the power splitter circuit, a portion of the first impedance matching circuit, and a portion of the second impedance matching circuit, wherein
the power splitter circuit further includes a plurality of splitter components physically coupled between the splitter input terminal, the first splitter output terminal, and the second splitter output terminal, wherein the plurality of splitter components is configured to receive the amplified input signal through the splitter input terminal and to divide a power of the amplified input signal to produce a first splitter output signal at the first splitter output terminal and to produce a second splitter output signal at the second splitter output terminal,
the first impedance matching circuit is configured to convey the first splitter output signal from the first splitter output terminal to the first device output terminal while performing a first impedance transformation between the first splitter output terminal and the first device output terminal, and
the second impedance matching circuit is configured to convey the second splitter output signal from the second splitter output terminal to the second device output terminal while performing a second impedance transformation between the second splitter output terminal and the second device output terminal.

19. The multiple-stage, multiple-path power amplifier of claim 14, wherein:
the first impedance matching circuit includes an inductance of the first device output terminal; and
the second impedance matching circuit includes an inductance of the second device output terminal.

20. The multiple-stage, multiple-path power amplifier of claim 14, wherein:
the multiple-stage, multiple-path power amplifier is a Doherty power amplifier;
the first power amplifier is a driver amplifier;
the second power amplifier is a carrier amplifier;
the third power amplifier is a peaking amplifier; and
the Doherty power amplifier further includes a combining node electrically coupled to the second and third transistor output terminals and to the system output terminal.
